(19) United States
(12) Patent Application Publication
(10) Pub. No.: US 2024/0363625 A1
(43) Pub. Date: Oct. 31, 2024

(54) SEMICONDUCTOR DEVICE

(71) Applicant: Samsung Electronics Co., Ltd., Suwon-si (KR)

(72) Inventors: Beom Jin Park, Suwon-si (KR); Myung Gil Kang, Suwon-si (KR); Dong Won Kim, Suwon-si (KR); Young Gwon Kim, Suwon-si (KR); Soo Jin Jeong, Suwon-si (KR)

(21) Appl. No.: 18/422,471

(22) Filed: Jan. 25, 2024

(30) Foreign Application Priority Data
Apr. 27, 2023 (KR) 10-2023-0055422

(51) Int. Cl. H01L 27/088; H01L 29/06; H01L 29/423; H01L 29/775; H01L 29/786

(52) U.S. Cl. CPC H01L 27/088; H01L 29/0673; H01L 29/42392; H01L 29/775; H01L 29/78696

(57) ABSTRACT

A semiconductor device is provided. The semiconductor includes a substrate having a first conductivity type; a well region having a second conductivity type in the substrate; an impurity implantation region having the first conductivity type in the well region; an element separation pattern in the substrate; a first fin pattern defined by the element separation pattern in the impurity implantation region; a second fin pattern defined by the element separation pattern in the well region; and a third fin pattern defined by the element separation pattern in the substrate, wherein the first fin pattern is a single fin, and an entirety of a lower boundary of the impurity implantation region is in contact with the well region.

### CROSS-REFERENCE TO RELATED APPLICATION

This application claims priority from Korean Patent Application No. 10-2023-0055422 filed on Apr. 27, 2023, in the Korean Intellectual Property Office, and all the benefits accruing therefrom under 35 U.S.C. 119, the contents of which in its entirety are herein incorporated by reference.

### FIELD

The present disclosure relates to a semiconductor device, and more particularly, to a semiconductor device including a vertical bipolar junction transistor.

### BACKGROUND

A semiconductor device may include an integrated circuit composed of metal oxide semiconductor (MOS) field effect transistors (MOSFET). As the size and design rules of semiconductor devices are gradually reduced, the downscaling of the MOS field effect transistors is also gradually accelerating. Operating characteristics of the semiconductor device may deteriorate as the size of the MOS field effect transistors is reduced. Accordingly, various methods for forming a semiconductor device with better performance while overcoming limitations due to high integration of the semiconductor device are being studied. As an example, for high integration of semiconductor devices, multi-bridge channel field effect transistors using a three-dimensional channel are being used, and structures of bipolar junction transistors compatible with the multi-bridge channel field effect transistors have been proposed.

### SUMMARY

Aspects of the present disclosure provide a semiconductor device having improved electrical characteristics.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device including a substrate having a first conductivity type; a well region having a second conductivity type in the substrate; an impurity implantation region having the first conductivity type in the well region; an element separation pattern in the substrate; a first fin pattern defined by the element separation pattern in the impurity implantation region; a second fin pattern defined by the element separation pattern in the well region; and a third fin pattern defined by the element separation pattern in the substrate, wherein the first fin pattern is a single fin pattern, and an entirety of a lower boundary of the impurity implantation region is in contact with the well region.

According to an aspect of the present disclosure, there is provided a semiconductor device including a substrate having a first conductivity type; a well region having a second conductivity type in the substrate; an impurity implantation region having the first conductivity type in the well region; and a first fin structure including first sacrificial patterns and first semiconductor patterns alternately stacked on the impurity implantation region, wherein an entirety of an upper boundary of the impurity implantation region is in contact with the first fin structure.

According to an aspect of the present disclosure, there is provided a semiconductor device including a substrate having a first conductivity type; a well region having a second conductivity type in the substrate, an impurity implantation region having the first conductivity type in the well region, an element separation pattern in the substrate, a first fin pattern defined by the element separation pattern in the impurity implantation region, a second fin pattern defined by the element separation pattern in the well region, a third fin pattern defined by the element separation pattern in the substrate, a first fin structure including first sacrificial patterns and first semiconductor patterns alternately stacked on the first fin pattern in a first direction perpendicular to an upper surface of the substrate, a second fin structure including second semiconductor patterns spaced apart from each other in the first direction on the second fin pattern, and a third fin structure including third semiconductor patterns spaced apart from each other in the first direction on the third fin pattern, wherein the first fin pattern is a single fin pattern and the first fin structure is a single fin structure, and in a second direction parallel to the upper surface of the substrate, a width of the first fin structure is the same as a width of the impurity implantation region.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary plan view for describing a semiconductor device according to some exemplary embodiments;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5, 6, and 7 are views for describing a semiconductor device according to some exemplary embodiments;

FIG. 8 is an exemplary plan view for describing a semiconductor device according to some exemplary embodiments;

FIG. 9 is a cross-sectional view taken along line A-A′ of FIG. 8;

FIG. 10 is a cross-sectional view taken along line B-B′ of FIG. 8;

FIG. 11 is a cross-sectional view taken along line C-C′ of FIG. 8;

FIG. 12 is an exemplary plan view for describing a semiconductor device according to some exemplary embodiments;

FIG. 13 is a cross-sectional view taken along line A-A′ of FIG. 12;

FIG. 14 is a cross-sectional view taken along line B-B′ of FIG. 12;

FIG. 15 is a cross-sectional view taken along line C-C′ of FIG. 12;

FIG. 16 is an exemplary plan view for describing a semiconductor device according to some exemplary embodiments;

FIG. 17 is a cross-sectional view taken along line A-A′ of FIG. 16;

FIG. 18 is a cross-sectional view taken along line B-B′ of FIG. 16;

FIG. 19 is a cross-sectional view taken along line C-C′ of FIG. 16;

FIG. 20 is an exemplary plan view for describing a semiconductor device according to some exemplary embodiments;

FIG. 21 is a cross-sectional view taken along line A-A′ of FIG. 20;

FIG. 22 is an exemplary plan view for describing a semiconductor device according to some exemplary embodiments; and

FIG. 23 is a cross-sectional view taken along line A-A′ of FIG. 22.

### DETAILED DESCRIPTION OF EMBODIMENTS

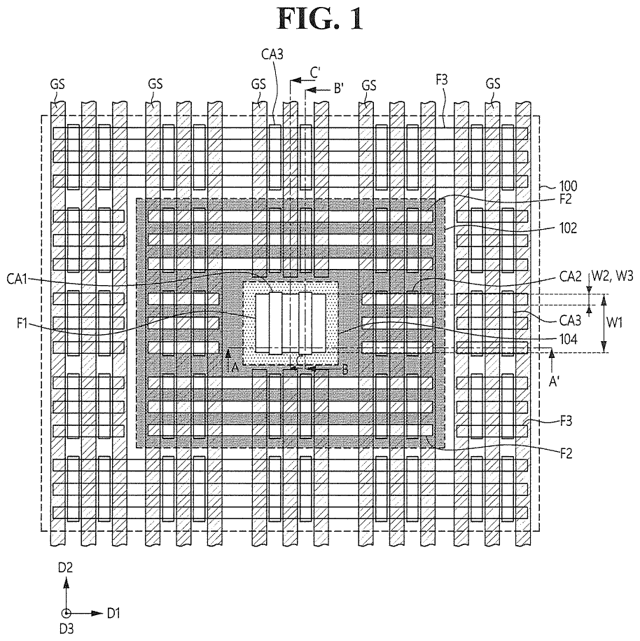

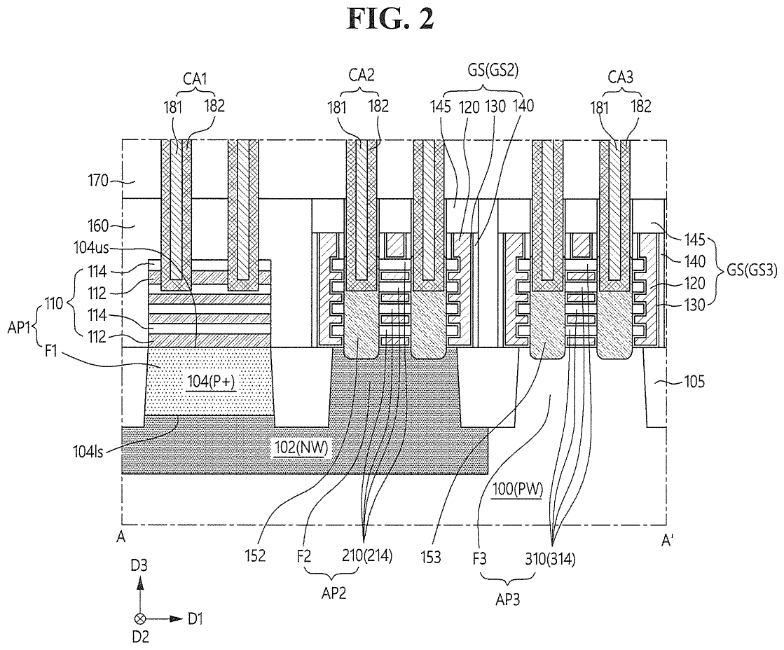

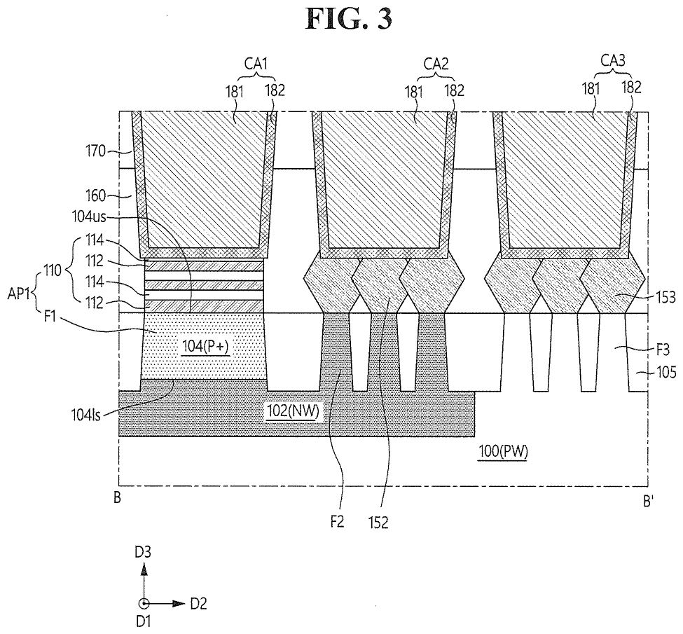

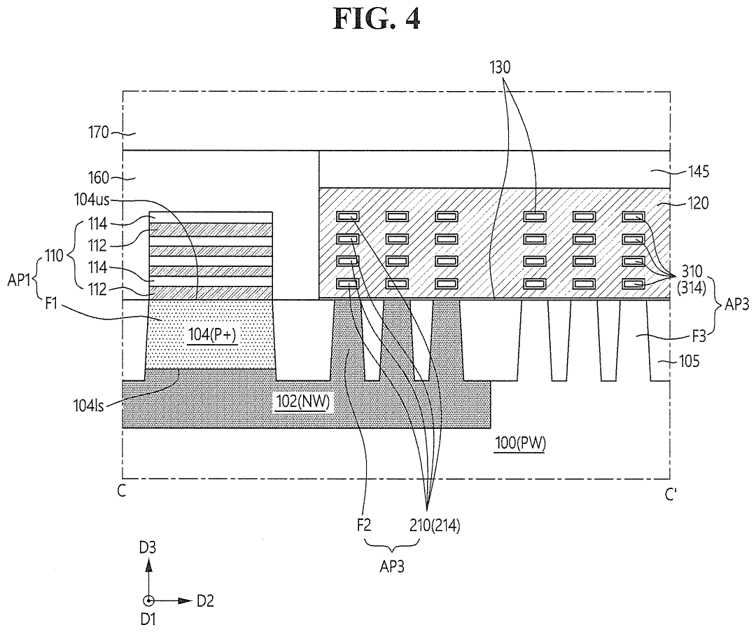

FIG. 1 is an exemplary plan view for describing a semiconductor device according to some exemplary embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. In FIG. 1, other components except for an element separation pattern 105 are illustrated.

Referring to FIGS. 1 to 4, a semiconductor device according to some exemplary embodiments may include a substrate 100, an element separation pattern 105, a first active pattern AP1, a second active pattern AP2, a third active pattern AP3, a gate structure GS, a first contact CA1, a second contact CA2, a third contact CA3, a first interlayer insulating film 160, and a second interlayer insulating film 170. The terms “first,” “second,” etc., may be used herein merely to distinguish one component, layer, direction, etc. from another.

The substrate 100 may be bulk silicon or silicon-on-insulator (SOI). Unlike this, the substrate 100 may also be a silicon substrate, or may also include another material, for example, silicon germanium, silicon germanium on insulator (SGOI), indium antimonide, a lead tellurium compound, indium arsenide, indium phosphide, gallium arsenide, or gallium antimonide. Alternatively, the substrate 100 may also have an epitaxial layer formed on a base substrate. The substrate 100 may have a first conductivity type.

A well region (NW) 102 may be disposed in the substrate 100. The well region 102 may have a second conductivity type different from the first conductivity type. An impurity implantation region (P+) 104 may be disposed in the well region NW. The impurity implantation region 104 may have the same conductivity type as that of the substrate 100. The impurity implantation region 104 may have the first conductivity type. As an example, the first conductivity type may be a P type, and the second conductivity type may be an N type. The substrate 100 and the well region 102 may be in contact with each other to form a PN junction. The well region 102 and the impurity implantation region 104 may be in contact with each other to form a PN junction.

A first direction D1 and a second direction D2 may be directions parallel to an upper surface of the substrate 100. The second direction D2 may intersect the first direction D1. The second direction D2 may be perpendicular to the first direction D1, for example. A third direction D3 may intersect the first direction D1 and the second direction D2. For example, the third direction D3 may be a direction perpendicular to the first and second directions D1 and D2 and perpendicular to the upper surface of the substrate 100. Hereinafter, an upper surface, an upper portion, a lower surface, a lower portion, and a lower layer are based on or relative to the third direction D3.

The element separation pattern 105 may be disposed in the substrate 100. The element separation pattern 105 may extend from the upper surface to a lower surface of the substrate 100, and a lower surface of the element separation pattern 105 may be disposed within the substrate 100. In plan view, the well region 102 may surround the impurity implantation region 104, and the substrate 100 may surround the well region 102. In plan view, the element separation pattern 105 may be disposed between the impurity implantation region 104 and the well region 102, and may be disposed between the well region 102 and the substrate 100. The element separation pattern 105 may include, for example, at least one of silicon oxide, silicon nitride, silicon oxynitride, or a combination thereof.

The first active pattern AP1 may be formed in the impurity implantation region 104. The first active pattern AP1 may include a first fin pattern F1 and a first fin structure 110. The second active pattern AP2 may include a second fin pattern F2 and a second fin structure 210. The third active pattern AP3 may be formed in the substrate 100. The third active pattern AP3 may include a third fin pattern F3 and a third fin structure 310.

The element separation pattern 105 may define the first fin pattern F1, the second fin pattern F2, and the third fin pattern F3. The element separation pattern 105 may be disposed between the first fin pattern F1, the second fin pattern F2, and the third fin pattern F3. The first fin pattern F1, the second fin pattern F2, and the third fin pattern F3 may protrude from a lower portion of the substrate 100. The element separation pattern 105 may be disposed on the lower portion of the substrate 100. For example, an upper surface of the first fin pattern F1, an upper surface of the second fin pattern F2, and/or an upper surface of the third fin pattern F3 may be on the same plane as (i.e., coplanar with) the upper surface of the element separation pattern 105. As another example, the upper surface of the first fin pattern F1, the upper surface of the second fin pattern F2, and/or the upper surface of the third fin pattern F3 may protrude from the upper surface of the element separation pattern 105.

In some exemplary embodiments, the first fin pattern F1 may consist of a single fin pattern having one plate shape (i.e., a substantially planar surface) having a size corresponding to that of the impurity implantation region 104. A plurality of second fin patterns F2 may be formed in the well region 102, and a plurality of third fin patterns F3 may be formed in the substrate 100. The second fin patterns F2 may elongate or longitudinally extend in the first direction D1 in the well region 102 and may be arranged in the second direction D2. The third fin patterns F3 may elongate or longitudinally extend in the first direction D1 in the substrate 100 and may be arranged in the second direction D2. That is, the number of first fin pattern F1 is one, but the number of second fin patterns F2 and third fin patterns F3 may be plural. An upper surface or boundary of the impurity implantation region 104 may be continuously formed and may be flat. That is, the upper boundary 104us of the impurity implantation region 104 may continuously extend along the substantially planar surface of the first fin pattern F1. An upper surface of the well region 102 may include a trench that is at least partially filled by the element separation pattern 105 defining the plurality of second fin patterns F2. An upper surface of the substrate 100 may include a trench that is at least partially filled by the element separation pattern 105 defining the plurality of third fin patterns F3.

In the second direction D2, a dimension or width W1 of the first fin pattern F1 may be greater than a dimension or width W2 of the second fin pattern F2 and a dimension or width W3 of the third fin pattern F3. The width W2 of the second fin pattern F2 and the width W3 of the third fin pattern F3 may be substantially the same. Hereinafter, the widths W1, W2, and W3 of the first to third fin patterns F1, F2, and F3 may refer to the widths W1, W2, and W3 of the upper surfaces of the first to third fin patterns F1, F2, and F3. The term “width” may be used to refer to a dimension of the fin patterns in one direction (e.g., along the second direction D2), while the term “length” may be used to refer to a dimension of the fin patterns in another direction (e.g., along the first direction D1), or vice versa. That is, the terms length and width may be used merely to differentiate dimensions taken along different directions from one another.

The first fin pattern F1 may be formed in the impurity implantation region 104. The impurity implantation region 104 may be continuously formed and may not include a trench. In plan view, the first fin pattern F1 may be defined by the element separation pattern 105 defining the impurity implantation region 104. The number of first fin pattern F1 may be one. An upper surface or boundary 104us of the impurity implantation region 104 may be the upper surface of the first fin pattern F1. In the first direction D1 and the second direction D2, a width of the upper surface or boundary 104us of the impurity implantation region 104 may be substantially the same as the width W1 of the upper surface of the first fin pattern F1. The first fin pattern F1 may be continuously formed (i.e., may continuously extend in the first and second directions) and may not include a trench.

The first fin pattern F1 may include the impurity implantation region 104. The entirety of the impurity implantation region 104 may be included in the first fin pattern F1. For example, the impurity implantation region 104 may be a portion of the first fin pattern F1.

The second fin pattern F2 may be a portion of the well region 102. The well region 102 may include a plurality of the second fin pattern F2. The well region 102 may extend along a lower surface or boundary 104ls of the impurity implantation region 104. The entirety of the lower boundary 104ls of the impurity implantation region 104 may be in direct contact with the well region 102. That is, the lower boundary 104ls of the impurity implantation region 104 may continuously extend along the well region 102 along an interface therebetween.

The third fin pattern F3 may be formed in the substrate 100. The third fin pattern F3 may be a portion of the substrate 100. The substrate 100 may include a plurality of the third fin pattern F3.

The first fin structure 110 may be disposed on the first fin pattern F1. The first fin structure 110 may have one plate or substantially planar shape having a size corresponding to that of the impurity implantation region 104. The number of first fin structure 110 may be one. That is, the first fin structure 110 may consist of a single fin structure. The first fin structure 110 may be continuously formed (i.e., may continuously extend in the first and second directions) and may not include a trench therein. One first fin structure 110 may be disposed on one first fin pattern F1.

A lower surface of the first fin structure 110 may be in contact with the upper surface or boundary 104us of the impurity implantation region 104. The entirety of the upper surface or boundary 104us of the impurity implantation region 104 may be in direct contact with the lower surface of the first fin structure 110 along an interface therebetween. An area of the upper surface 104us or boundary of the impurity implantation region 104 may be substantially the same as an area of the lower surface of the first fin structure 110. For example, in the first direction D1 and the second direction D2, a width of the upper surface 104us of the impurity implantation region 104 may be substantially the same as that of the lower surface of the first fin structure 110.

The first fin structure 110 may include a plurality of first sacrificial patterns 112 and a plurality of first semiconductor patterns 114 alternately stacked on the first fin pattern F1. The first sacrificial pattern 112 and the first semiconductor pattern 114 may be alternately stacked along the third direction D3. As used herein, a “sacrificial” pattern may refer to a semiconductor pattern that is non-functional with respect to electrical conduction, but may be present (i.e., is not necessarily removed) in the completed device. The first fin structure 110 may have the first conductivity type. The first fin structure 110 may include impurities of the first conductivity type.

The second fin structure 210 may be disposed on the second fin pattern F2. The second fin structure 210 may include a plurality of second semiconductor patterns 214. The plurality of second semiconductor patterns 214 may be spaced apart from the second fin pattern F2 in the third direction D3. The respective second semiconductor patterns 214 may be spaced apart from each other in the third direction D3.

The third fin structure 310 may be disposed on the third fin pattern F3. The third fin structure 310 may include a plurality of third semiconductor patterns 314. The plurality of third semiconductor patterns 314 may be spaced apart from the third fin pattern F3 in the third direction D3. The respective third semiconductor patterns 314 may be spaced apart from each other in the third direction D3.

For example, in the second direction D2, a width of the second semiconductor pattern 214 and a width of the third semiconductor pattern 314 may increase or decrease as a distance from the substrate 100 increases. As another example, in the second direction D2, the width of the second semiconductor pattern 214 and the width of the third semiconductor pattern 314 may be constant.

The first sacrificial pattern 112 may include a material (e.g., a semiconductor material) that is different from that of the first semiconductor pattern 114. The first to third semiconductor patterns 114, 214, and 314 may include the same material as each other. For example, the first sacrificial pattern 112 may include silicon germanium (SiGe), and the first to third semiconductor patterns 114, 214, and 314 may include silicon (Si).

In some exemplary embodiments, the plurality of gate structures GS may include a second gate structure GS2 and a third gate structure GS3. The gate structure GS may not be disposed on the first fin pattern F1. The gate structure GS may longitudinally extend or may be elongated in the second direction D2. The gate structures GS may be arranged or spaced apart in the first direction D1.

The second gate structure GS2 may be disposed on the well region 102. The second gate structure GS2 may be disposed on the second active pattern AP2. The second gate structure GS2 may intersect the second active pattern AP2. The second gate structure GS2 may intersect the second fin pattern F2. The second gate structure GS2 may surround the second semiconductor pattern 214. The second gate structure GS2 may cover an end or respective ends of the second semiconductor pattern 214. A first source/drain pattern 152 may be disposed on a side surface of the second gate structure GS2.

The third gate structure GS3 may be disposed on the substrate 100. The third gate structure GS3 may be disposed on the third active pattern AP3. The third gate structure GS3 may intersect the third active pattern AP3. The third gate structure GS3 may intersect the third fin pattern F3. The third gate structure GS3 may surround the third semiconductor pattern 314. The third gate structure GS3 may cover an end or respective ends of the third semiconductor pattern 314. A second source/drain pattern 153 may be disposed on a side surface of the third gate structure GS3.

In some exemplary embodiments, the gate structure GS may include a gate electrode 120, a gate insulating film 130, a gate spacer 140, and a gate capping pattern 145.

The gate electrode 120 may be disposed on the second fin pattern F2 and the third fin pattern F3. The gate electrode 120 may intersect the second fin pattern F2 and the third fin pattern F3. The gate electrode 120 may surround the second semiconductor pattern 214 and the third semiconductor pattern 314. The gate electrode 120 may cover an end or respective ends of the second semiconductor pattern 214 and an end of the third semiconductor pattern 314. A portion of the gate electrode 120 may be disposed between adjacent second semiconductor patterns 214, between the second fin pattern F2 and the second semiconductor pattern 214 disposed on the lowermost layer (also referred to as the lowermost semiconductor pattern among the semiconductor patterns), between adjacent third semiconductor patterns 314, and between the third fin pattern F3 and the lowermost third semiconductor pattern 314. The gate electrode 120 may be a dummy gate electrode.

The gate electrode 120 may include at least one of a metal, a metal alloy, conductive metal nitride, metal silicide, a doped semiconductor material, conductive metal oxide, or conductive metal oxynitride.

The gate insulating film 130 may extend along a portion of the upper surface of the element separation pattern 105, the upper surface of the second fin pattern F2, and the upper surface of the third fin pattern F3. The gate insulating film 130 may be disposed along a periphery of the second semiconductor pattern 214 and a periphery of the third semiconductor pattern 314. The gate electrode 120 may be disposed on the gate insulating film 130. The gate insulating film 130 may be disposed between the gate electrode 120 and the second semiconductor pattern 214 and between the gate electrode 120 and the third semiconductor pattern 314. A portion of the gate insulating film 130 may be disposed between adjacent second semiconductor patterns 214, between the second fin pattern F2 and the lowermost second semiconductor pattern 214, between adjacent third semiconductor patterns 314, and between the third fin pattern F3 and the lowermost third semiconductor pattern 314.

The gate insulating film 130 may also be a single film or may also include an interface film and a high-k insulating film.

The gate insulating film 130 may include silicon oxide, silicon-germanium oxide, germanium oxide, silicon oxynitride, silicon nitride, or a high-k material having a dielectric constant greater than that of the silicon oxide.

The gate spacer 140 may be disposed on a sidewall of the gate electrode 120. The gate spacer 140 may not be disposed between the second fin pattern F2 and the lowermost second semiconductor pattern 214, between adjacent second semiconductor patterns 214, between the third fin pattern F3 and the lowermost third semiconductor pattern 314, and between adjacent third semiconductor patterns 314. An inner sidewall of the gate spacer 140 may face the gate electrode 120. The gate insulating film 130 may extend along the inner sidewall of the gate spacer 140. The gate insulating film 130 may be in contact with the gate spacer 140.

The gate spacer 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

The gate capping pattern 145 may be disposed on the gate electrode 120 and the gate spacer 140. Alternatively, the gate capping pattern 145 may be disposed between the gate spacers 140.

The gate capping pattern 145 may include, for example, at least one of silicon nitride (SiN), silicon oxynitride (SiON), silicon carbonitride (SiCN), silicon oxycarbonitride (SiOCN), or a combination thereof.

The first source/drain pattern 152 may be disposed on the second active pattern AP2. The first source/drain pattern 152 may be disposed on the second fin pattern F2. The first source/drain pattern 152 may be connected to the second semiconductor pattern 214. The first source/drain pattern 152 may be in contact with the second semiconductor pattern 214. The first source/drain pattern 152 may be disposed between the second gate structures GS2 adjacent to each other in the first direction D1. For example, the first source/drain patterns 152 may be disposed on both or opposing side surfaces of the second gate structure GS2, but may not be disposed on a side surface of the second gate structure GS2 on the element separation pattern 105. The first source/drain pattern 152 may penetrate through the second semiconductor patterns 214 and the second fin pattern F2 and may be connected to the well region 102. The term “connected” may be used herein to refer to a physical and/or electrical connection.

The first source/drain pattern 152 may be formed from the second active pattern AP2 by an epitaxial growth method. The first source/drain pattern 152 may include impurities having the second conductivity type.

The second source/drain pattern 153 may be disposed on the third active pattern AP3. The second source/drain pattern 153 may be disposed on the third fin pattern F3. The second source/drain pattern 153 may be connected to the third semiconductor patterns 314. The second source/drain pattern 153 may be in contact with the third semiconductor patterns 314. The second source/drain pattern 153 may be disposed between the third gate structures GS3 adjacent to each other in the first direction D1. For example, the second source/drain patterns 153 may be disposed on both or opposing side surfaces of the third gate structure GS3, but may not be disposed on a side surface of the third gate structure GS3 on the element separation pattern 105. The second source/drain pattern 153 may penetrate through one or more of the third semiconductor patterns 314 and the third fin pattern F3 and may be connected to the substrate 100.

The second source/drain pattern 153 may be formed from the third active pattern AP3 by an epitaxial growth method. The second source/drain pattern 153 may include impurities having the first conductivity type.

The first interlayer insulating film 160 may be formed on the substrate 100. The first interlayer insulating film 160 may cover the substrate 100, the first to third fin structures 110, 210, and 310, and the first and second source/drain patterns 152 and 153. An upper surface of the first interlayer insulating film 160 may expose an upper surface of the gate capping pattern 145. For example, the upper surface of the first interlayer insulating layer or film 160 may be on the same plane as (i.e., coplanar with) the upper surface of the gate capping pattern 145. The second interlayer insulating film 170 may be disposed on the first interlayer insulating film 160. The second interlayer insulating film 170 may cover the upper surface of the gate capping pattern 145.

The first interlayer insulating film 160 may include, for example, at least one of silicon oxide, silicon nitride, silicon oxynitride, of a low-k material. The second interlayer insulating film 170 may include at least one of an oxide film, a nitride film, or an oxynitride film.

In some exemplary embodiments, the first contact CA1 may be connected to the first fin structure 110, the second contact CA2 may be connected to the first source/drain pattern 152, and the third contact CA3 may be connected to the second source/drain pattern 153.

A plurality of first contacts CA1 may be disposed on the first active pattern AP1. The first contact CA1 may penetrate through the first and second interlayer insulating films 160 and 170 and be connected to the first fin structure 110. The first contact CA1 may penetrate through a portion of the first fin structure 110, and a lower surface of the first contact CA1 may be disposed within the first fin structure 110. For example, the first contact CA1 may be connected to one or more of the first semiconductor patterns 114.

A plurality of second contacts CA2 may be disposed on the second active pattern AP2. The second contact CA2 may penetrate through the first and second interlayer insulating films 160 and 170 and be disposed on the first source/drain pattern 152. The second contact CA2 may be connected to the first source/drain pattern 152.

A plurality of third contacts CA3 may be disposed on the third active pattern AP3. The third contact CA3 may penetrate through the first and second interlayer insulating films 160 and 170 and be disposed on the second source/drain pattern 153. The third contact CA3 may be connected to the second source/drain pattern 153.

The first to third contacts CA1, CA2, and CA3 may include a barrier metal film 182 and a metal film 181, respectively. The metal film 181 may penetrate through the first and second interlayer insulating films 160 and 170. The barrier metal film 182 may extend along a side surface and a lower surface of the metal film 181.

Each of the barrier metal films 182 may include, for example, conductive metal nitride such as titanium nitride, tantalum nitride, or tungsten nitride. The metal film 181 may include, for example, a metal material such as cobalt (Co), titanium (Ti), tantalum (Ta), ruthenium (Ru), tungsten (W), or cobalt tungsten phosphorus (CoWP).

The impurity implantation region 104, the first active pattern AP1, and the first contact CA1 may constitute an emitter of a vertical bipolar junction transistor. The well region 102, the second active pattern AP2, the second gate structure GS2, the first source/drain pattern 152, and the second contact CA2 may constitute a base of the vertical bipolar junction transistor. The substrate 100, the third active pattern AP3, the second source/drain pattern 153, the third gate structure GS3, and the third contact CA3 may constitute a collector of the vertical bipolar junction transistor. The first and second gate structures GS2 and GS3 may be electrically floating dummy gate structures.

In the semiconductor device according to some exemplary embodiments, a power line for supplying power to the semiconductor device may be disposed on the lower surface of the substrate 100. The power line may be connected to the first to third contacts CA1, CA2, and CA3 through a buried conductive pattern in the substrate 100. For example, a signal line supplying an operation signal of the semiconductor device may be disposed on the upper surface of the substrate 100. As another example, a signal line supplying an operation signal of the semiconductor device may be disposed on the lower surface of the substrate 100.

The vertical bipolar junction transistor according to some exemplary embodiments may include a lower transistor and an upper transistor. Each of the first to third fin structures 110, 210, and 310 may include a lower fin structure and an upper fin structure, and each of the first source/drain pattern 152 and the second source/drain pattern 153 may include a lower source/drain pattern and an upper source/drain pattern stacked on the lower source/drain pattern. A separation layer may be formed between the lower fin structure and the upper fin structure and between the lower source/drain pattern and the upper source/drain pattern.

In the semiconductor device according to some exemplary embodiments, the impurity implantation region 104 may not include the element separation pattern 105 therein. The impurity implantation region 104 may include one active pattern AP1, e.g., a single or continuous active pattern AP1. In plan view, one active pattern AP1 corresponding to the area of the impurity implantation region 104 may be formed. Since the upper surface of the first active pattern AP1 in the impurity implantation region 104 is continuously formed (e.g., continuously extends in first and second directions), the first active pattern AP1 may be a planar type having an upper surface whose entirety is flat. Accordingly, compared to the case where the impurity implantation region 104 includes the plurality of second and third fin patterns F2 and F3 like the second active pattern AP2 or the third active pattern AP3, an area or interface where the lower surface or boundary 104ls of the impurity implantation region 104 and the well region 102 form a PN junction may increase. In addition, compared to the case where the impurity implantation region 104 includes the plurality of second and third fin patterns F2 and F3 like the second active pattern AP2 or the third active pattern AP3, a contact area between the first fin structure 110 and the first contact CA1 may increase. Therefore, current density may be increased and a leakage current may be reduced.

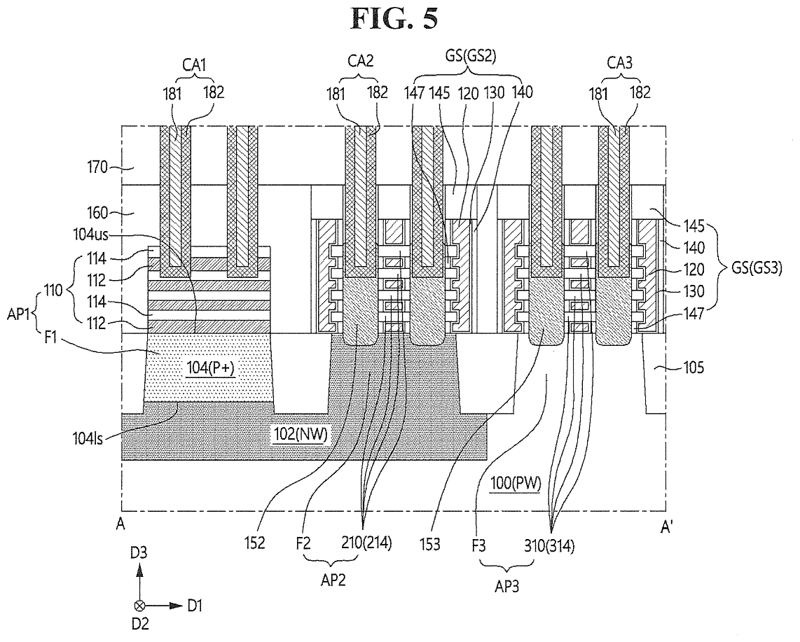

FIGS. 5 to 7 are views for describing a semiconductor device according to some exemplary embodiments. For reference, FIGS. 5 to 7 are cross-sectional views taken along line A-A′ of FIG. 1. For convenience of explanation, points different from those described with reference to FIGS. 1 to 4 will be mainly described.

Referring to FIG. 5, in the semiconductor device according to some embodiments, each of the second gate structure GS2 and the third gate structure GS3 may further include an inner spacer 147.

The inner spacer 147 may be disposed between adjacent second semiconductor patterns 214 and between the second fin pattern F2 and the lowermost second semiconductor pattern 214. The inner spacer 147 may be in contact with the gate insulating film 130 between adjacent second semiconductor patterns 214 and between the second fin pattern F2 and the lowermost second semiconductor pattern 214. The inner spacer 147 may define a portion of the first source/drain pattern 152.

The inner spacer 147 may be disposed between adjacent third semiconductor patterns 314 and between the third fin pattern F3 and the lowermost third semiconductor pattern 314. The inner spacer 147 may be in contact with the gate insulating film 130 between adjacent third semiconductor patterns 314 and between the third fin pattern F3 and the lowermost third semiconductor pattern 314. The inner spacer 147 may define a portion of the second source/drain pattern 153.

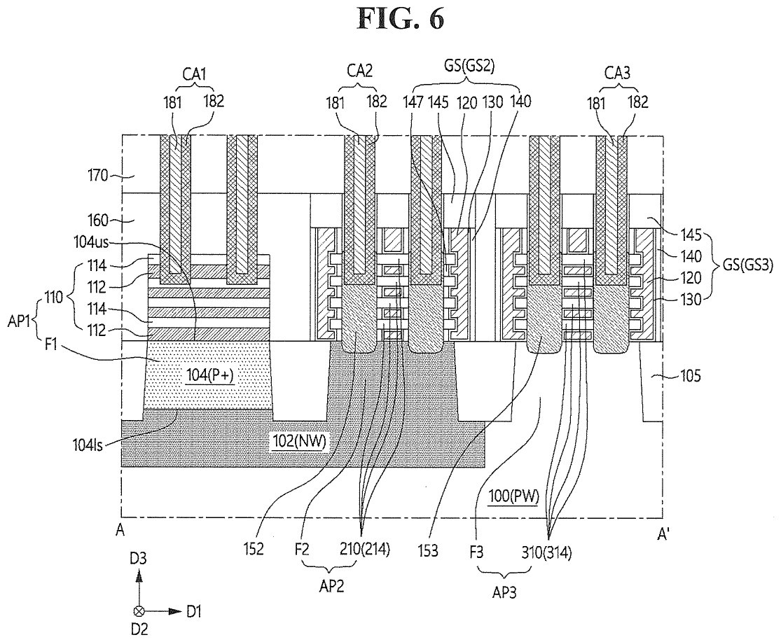

Referring to FIG. 6, in the semiconductor device according to some embodiments, the second gate structure GS2 may further include an inner spacer 147 and the third gate structure GS3 may not further include an inner spacer 147. The inner spacer 147 of the second gate structure GS2 may be substantially the same as the inner spacer 147 of the second gate structure GS2 described with reference to FIG. 5.

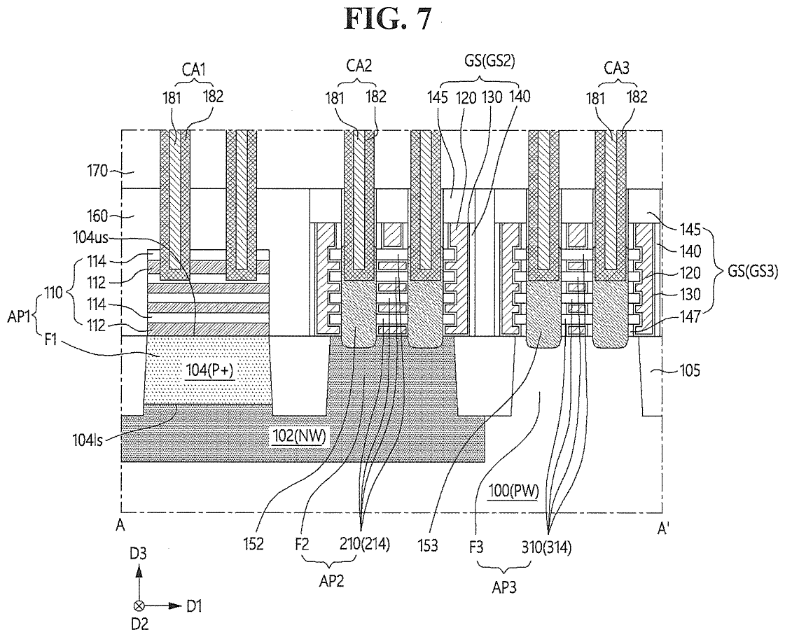

Referring to FIG. 7, in the semiconductor device according to some embodiments, the third gate structure GS3 may further include an inner spacer 147 and the second gate structure GS2 may not further include an inner spacer 147. The inner spacer 147 of the third gate structure GS3 may be substantially the same as the inner spacer 147 of the third gate structure GS3 described with reference to FIG. 5.

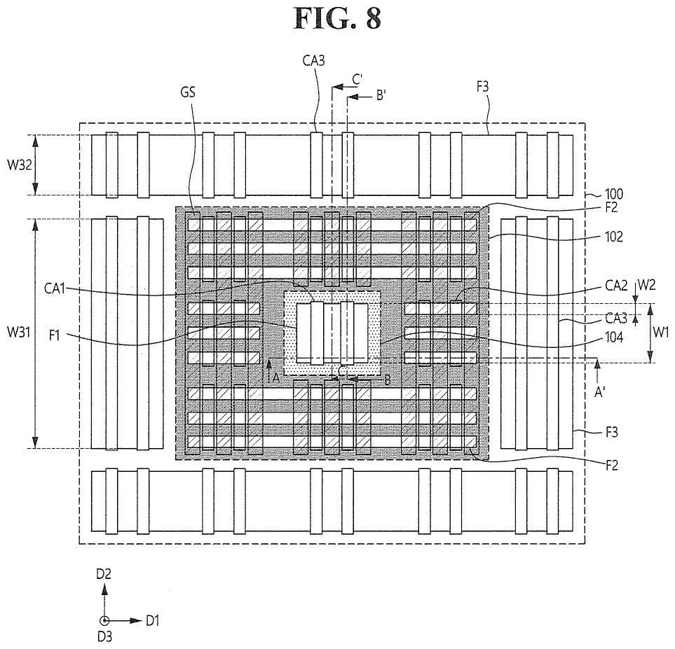

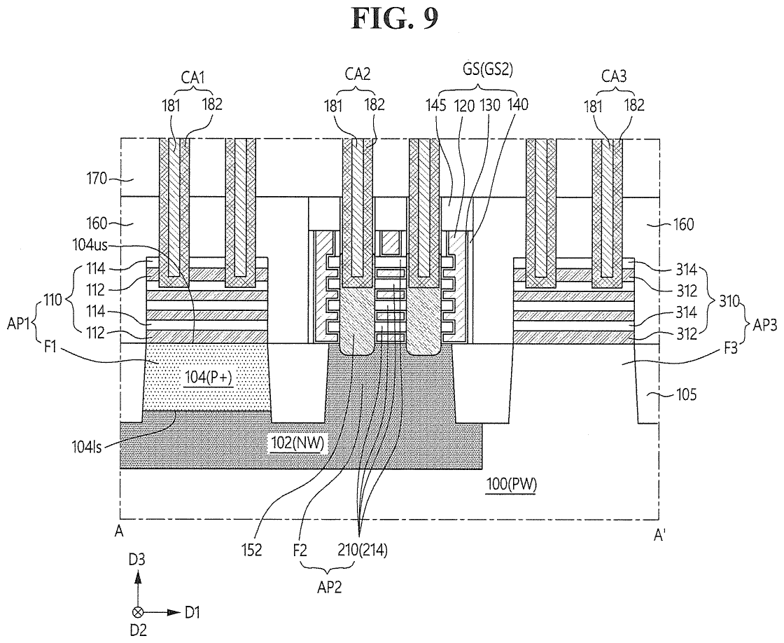

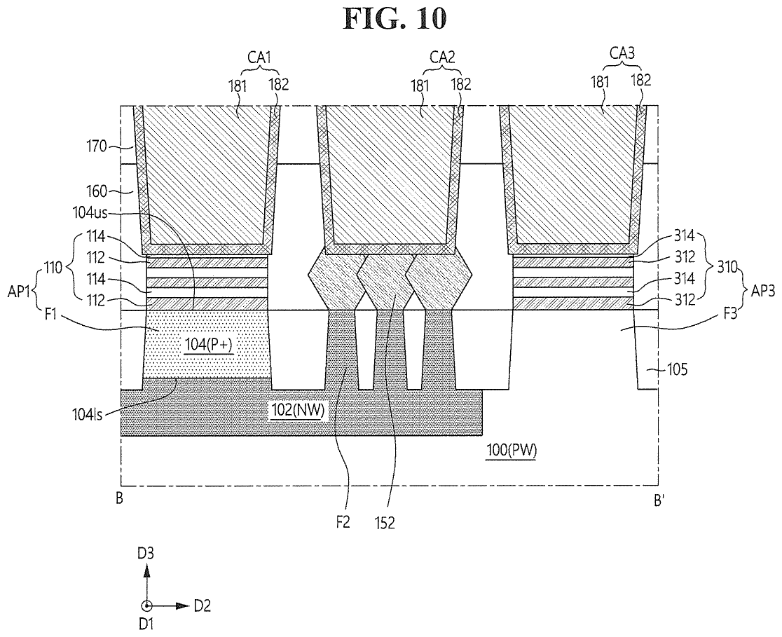

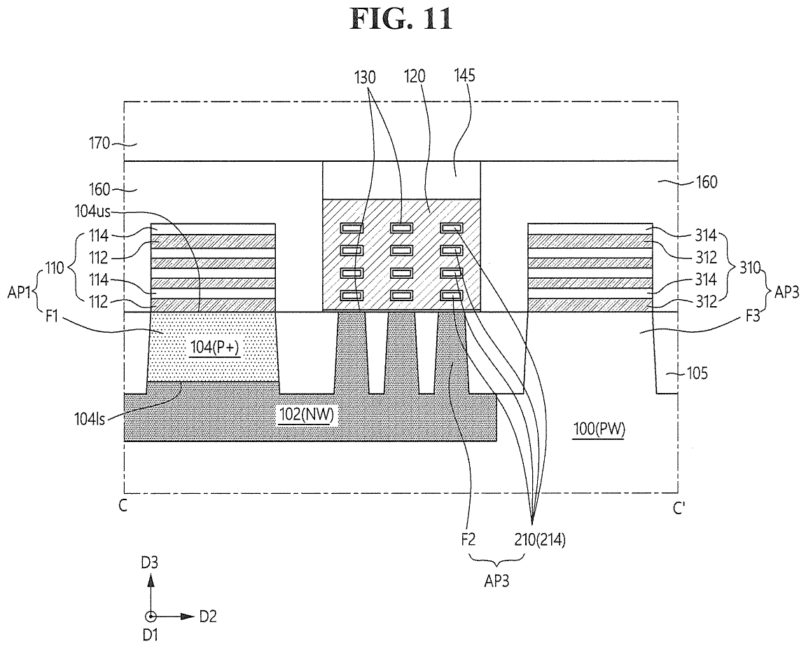

FIG. 8 is an exemplary plan view for describing a semiconductor device according to some exemplary embodiments. FIG. 9 is a cross-sectional view taken along line A-A′ of FIG. 8. FIG. 10 is a cross-sectional view taken along line B-B′ of FIG. 8. FIG. 11 is a cross-sectional view taken along line C-C′ of FIG. 8. In FIG. 8, other components except for an element separation pattern 105 are briefly illustrated. For convenience of explanation, points different from those described with reference to FIGS. 1 to 7 will be mainly described.

Referring to FIGS. 8 to 11, in the semiconductor device according to some exemplary embodiments, the first fin pattern F1 and the plurality of third fin patterns F3 may have a plate shape.

For example, the plurality of third fin patterns F3 may include third fin patterns F3 of one plate shape disposed on the upper and lower sides of the well region 102 in the second direction D2 and on the left and right sides thereof in the first direction D1, respectively. Hereinafter, the upper and lower sides are based on the second direction D2, and the left and right sides are based on the first direction D1. The third fin patterns F3 disposed on the upper, lower, left, and right sides of the well region 102, respectively, may have a plate shape having a size corresponding to that of the substrate 100 disposed on the upper, lower, left, and right sides of the well region 102, respectively. The third fin patterns F3 disposed on the upper and lower sides of the well region 102, respectively, may longitudinally extend or may be elongated in the first direction D1, and the third fin patterns F3 disposed on the left and right sides of the well region 102, respectively, may longitudinally extend or may be elongated in the second direction D2.

In the second direction D2, a width W31 of the third fin patterns F3 disposed on the left and right sides of the well region 102 may be greater than a width W2 of the second fin pattern F2. In the second direction D2, a width W32 of the third fin patterns F3 disposed on the upper and lower sides of the well region 102 may be greater than the width W2 of the second fin pattern F2.

The third fin structure 310 may be disposed on each of the third fin patterns F3. The third fin structure 310 may have one plate shape having a size corresponding to each of the third fin patterns F3. One third fin structure 310 may be disposed on one third fin structure F3. A lower surface of the third fin structure 310 may be in contact with the upper surface of the substrate 100. The entirety of the upper surface of the substrate 100 may be in direct contact with the lower surface of the third fin structure 310 along an interface therebetween. For example, in the first direction D1 and/or the second direction D2, a width of the upper surface of the third fin pattern F3 may be substantially the same as that of the lower surface of the third fin structure 310.

The third fin structure 310 may include a plurality of third sacrificial patterns 312 and a plurality of third semiconductor patterns 314 alternately stacked on the third fin pattern F3. The third sacrificial pattern 312 and the third semiconductor pattern 314 may be alternately stacked along the third direction D3.

The third sacrificial pattern 312 may include a material (e.g., a semiconductor material) different from that of the third semiconductor pattern 314. The first and third sacrificial patterns 112 and 312 may include the same material, and the first to third semiconductor patterns 114, 214, and 314 may include the same material. For example, the first and third sacrificial patterns 112 and 312 may include silicon germanium (SiGe), and the first to third semiconductor patterns 114, 214, and 314 may include silicon (Si).

As another example, the third fin pattern F3 may have one plate shape. The third fin patterns F3 disposed on the upper, lower, left, and right sides of the well region 102, respectively, may be connected to each other, and may have a shape surrounding the well region 102 in plan view. The third fin structure 310 may also have one plate shape having a size corresponding to one third fin patterns F3.

In some exemplary embodiments, the gate structure GS may include a second gate structure GS2. The gate structure GS may not be disposed on the first fin pattern F1 and the third fin pattern F3.

In some exemplary embodiments, the first contact CA1 may be connected to the first fin structure 110, the second contact CA2 may be connected to the first source/drain pattern 152, and the third contact CA3 may be connected to the third fin structure 310.

The third contact CA3 may penetrate through the first and second interlayer insulating films 160 and 170 and be connected to the third fin structure 310. The third contact CA3 may penetrate through a portion of the third fin structure 310, and a lower surface of the third contact CA3 may be disposed within the third fin structure 310. For example, the third contact CA3 may be connected to one or more of the third semiconductor patterns 314.

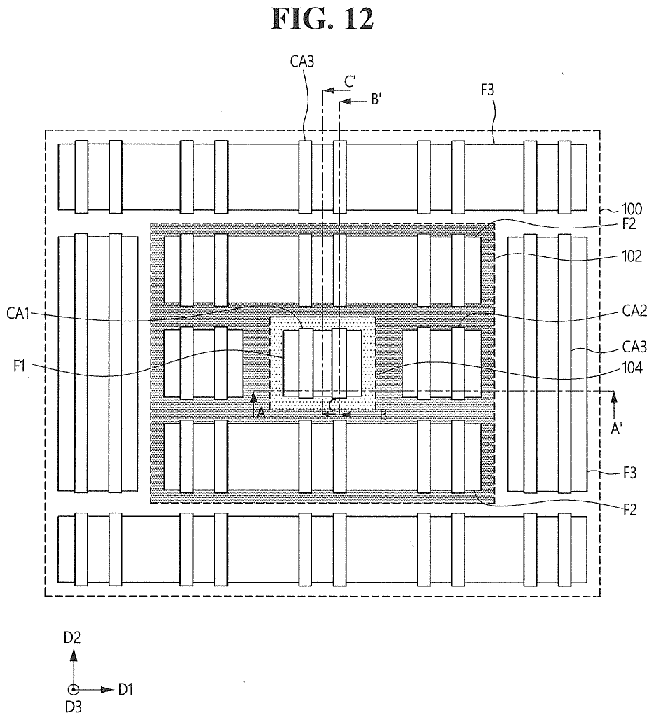

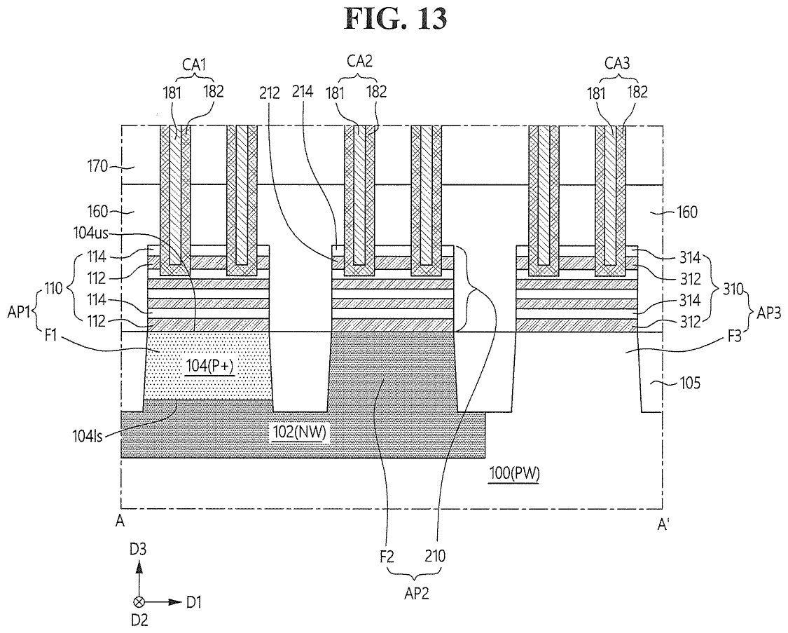

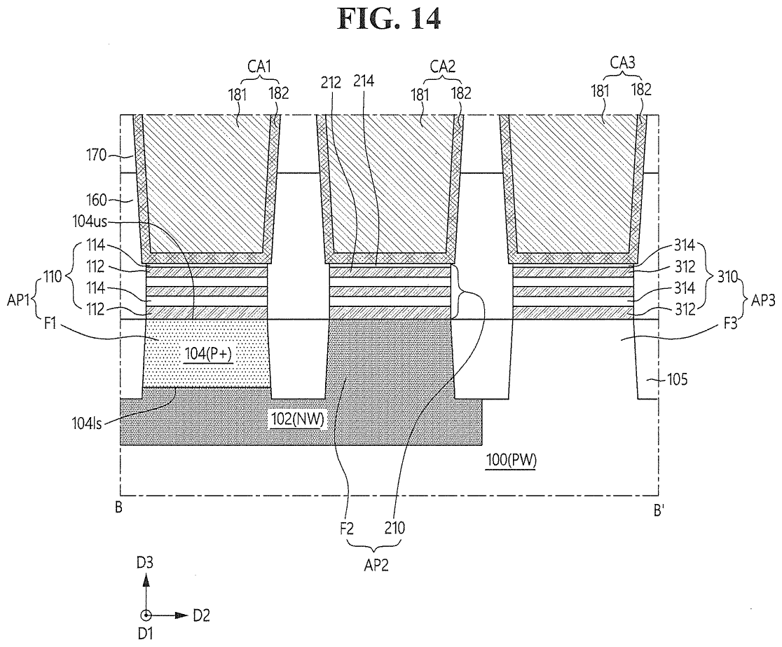

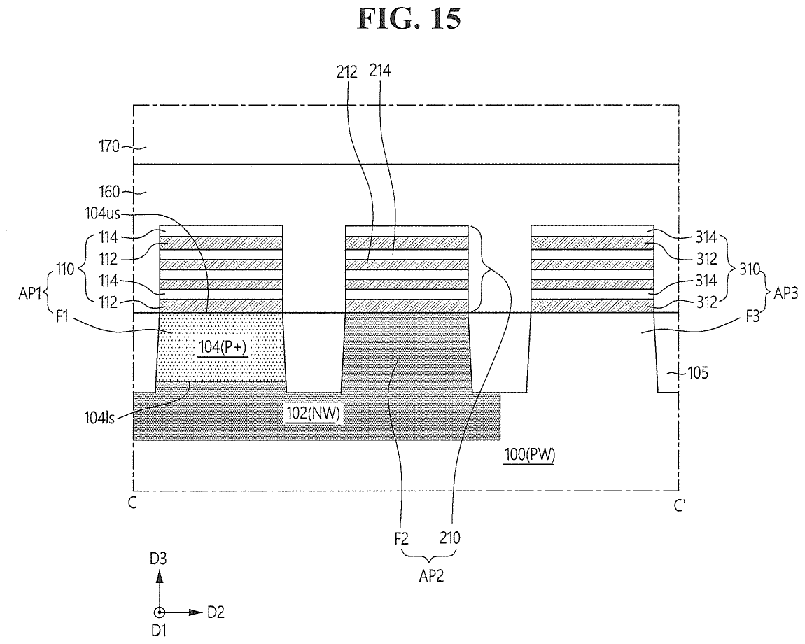

FIG. 12 is an exemplary plan view for describing a semiconductor device according to some exemplary embodiments. FIG. 13 is a cross-sectional view taken along line A-A′ of FIG. 12. FIG. 14 is a cross-sectional view taken along line B-B′ of FIG. 12. FIG. 15 is a cross-sectional view taken along line C-C′ of FIG. 12. In FIG. 12, other components except for an element separation pattern 105 are briefly illustrated. For convenience of explanation, points different from those described with reference to FIGS. 1 to 11 will be mainly described.

Referring to FIGS. 12 to 15, in the semiconductor device according to some exemplary embodiments, the first fin pattern F1, the plurality of second fin patterns F2, and the plurality of third fin patterns F3 may have a plate shape.

For example, the plurality of second fin patterns F2 may include the second fin patterns F2 of one plate shape disposed on the upper, lower, left, and right sides of the impurity implantation region 104, respectively. The second fin patterns F2 disposed on the upper, lower, left, and right sides of the impurity implantation region 104, respectively, may have a plate shape having a size corresponding to that of the well region 102 disposed on the upper, lower, left, and right sides of the impurity implantation region 104, respectively. The second fin patterns F2 disposed on the upper and lower sides of the impurity implantation region 104, respectively, may longitudinally extend or may be elongated in the first direction D1, and the second fin patterns F2 disposed on the left and right sides of the impurity implantation region 104, respectively, may longitudinally extend or may be elongated in the second direction D2.

The second fin structure 210 may be disposed on each of the second fin patterns F2. The second fin structure 210 may have one plate shape having a size corresponding to each of the second fin patterns F2. One second fin structure 210 may be disposed on one second fin structure F2. A lower surface of the second fin structure 210 may be in contact with the upper surface of the well region 102. The entirety of the upper surface of the well region 102 may be in direct contact with the lower surface of the second fin structure 210 along an interface therebetween. For example, in the first direction D1 and/or the second direction D2, a width of the upper surface of the second fin pattern F2 may be substantially the same as that of the lower surface of the second fin structure 210.

The second fin structure 210 may include a plurality of second sacrificial patterns 212 and a plurality of second semiconductor patterns 214 alternately stacked on the second fin pattern F2. The second sacrificial pattern 212 and the second semiconductor pattern 214 may be alternately stacked along the third direction D3.

The second sacrificial pattern 212 may include a material (e.g., a semiconductor material) different from that of the second semiconductor pattern 214. The first to third sacrificial patterns 112, 212, and 312 may include the same material, and the first to third semiconductor patterns 114, 214, and 314 may include the same material. For example, the first to third sacrificial patterns 112, 212, and 312 may include silicon germanium (SiGe), and the first to third semiconductor patterns 114, 214, and 314 may include silicon (Si).

As another example, the second fin pattern F2 may have one plate shape. The second fin patterns F2 disposed on the upper, lower, left, and right sides of the impurity implantation region 104, respectively, may be connected to each other, and may have a shape surrounding the impurity implantation region 104 in plan view. The second fin structure 210 may also have one plate shape having a size corresponding to one second fin patterns F2.

The semiconductor device according to some exemplary embodiments may not include the gate structure (GS in FIGS. 1 to 11).

In some exemplary embodiments, the first contact CA1 may be connected to the first fin structure 110, the second contact CA2 may be connected to the second fin structure 210, and the third contact CA3 may be connected to the third fin structure 310.

The second contact CA2 may penetrate through the first and second interlayer insulating films 160 and 170 and be connected to the second fin structure 210. The second contact CA2 may penetrate through a portion of the second fin structure 210, and a lower surface of the second contact CA2 may be disposed within the second fin structure 210. For example, the second contact CA2 may be connected to one or more of the second semiconductor patterns 214.

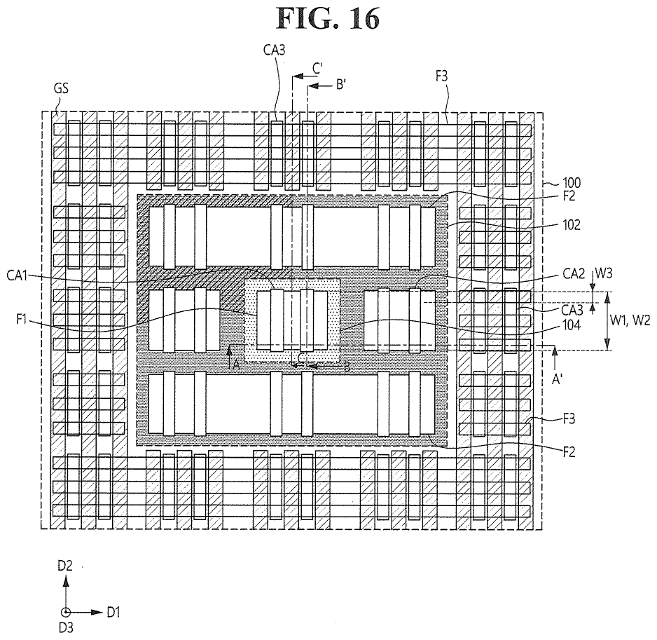

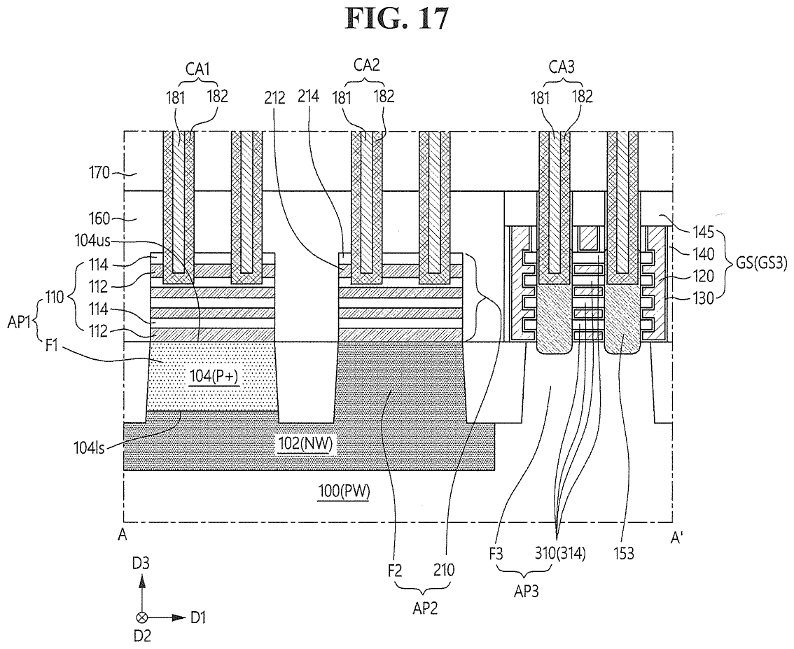

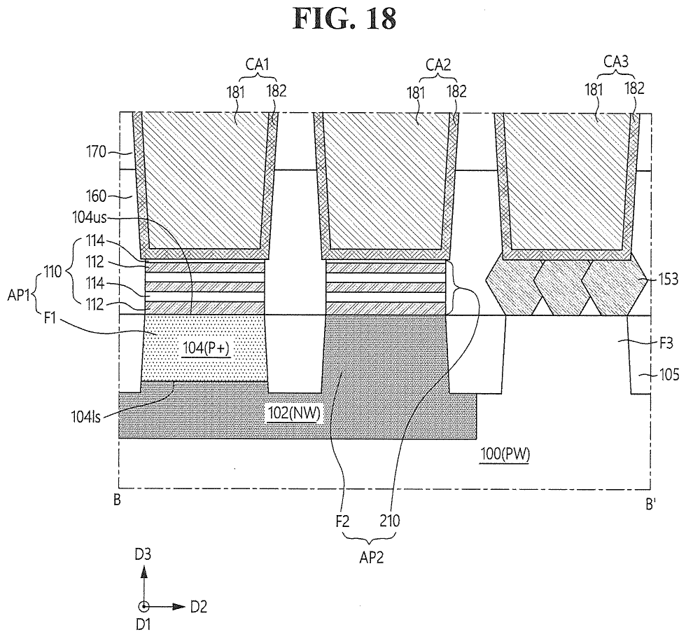

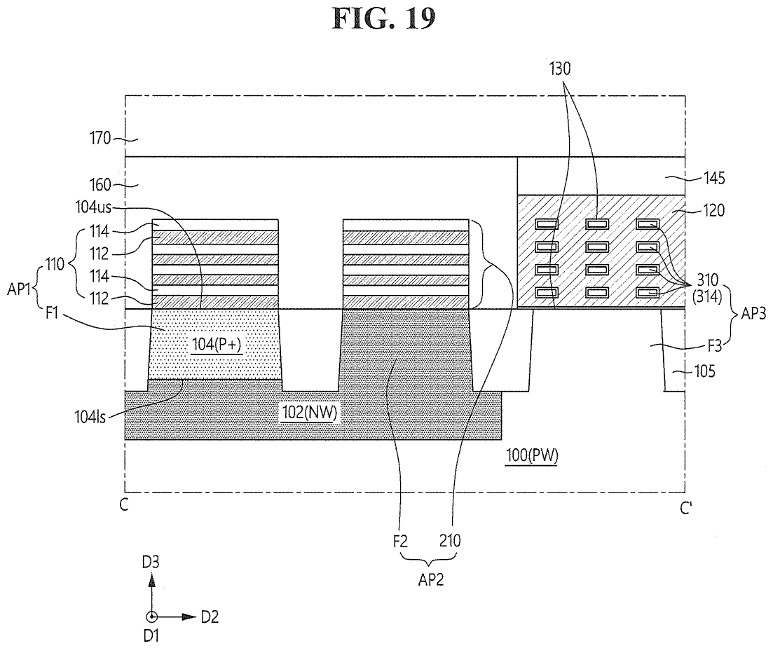

FIG. 16 is an exemplary plan view for describing a semiconductor device according to some exemplary embodiments. FIG. 17 is a cross-sectional view taken along line A-A′ of FIG. 16. FIG. 18 is a cross-sectional view taken along line B-B′ of FIG. 16. FIG. 19 is a cross-sectional view taken along line C-C′ of FIG. 16. In FIG. 16, other components except for an element separation pattern 105 are briefly illustrated. For convenience of explanation, points different from those described with reference to FIGS. 1 to 15 will be mainly described.

Referring to FIGS. 16 to 19, in the semiconductor device according to some exemplary embodiments, the first fin pattern F1 and the plurality of second fin patterns F2 may have a plate shape.

In some exemplary embodiments, the gate structure GS may include a third gate structure GS3 on the third fin pattern F3. The gate structure GS may not be disposed on the first fin pattern F1 and the second fin pattern F2.

In some exemplary embodiments, the first contact CA1 may be connected to the first fin structure 110, the second contact CA2 may be connected to the second fin structure 210, and the third contact CA3 may be connected to the second source/drain pattern 153.

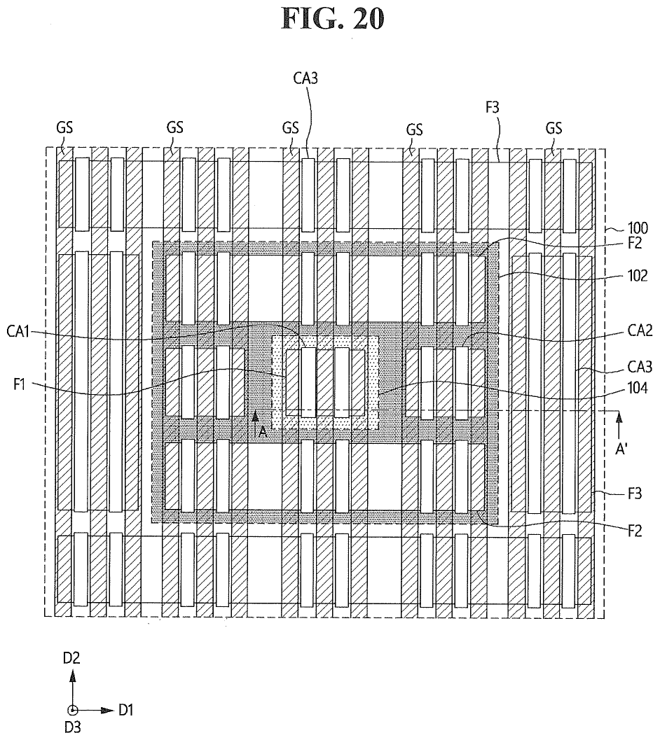

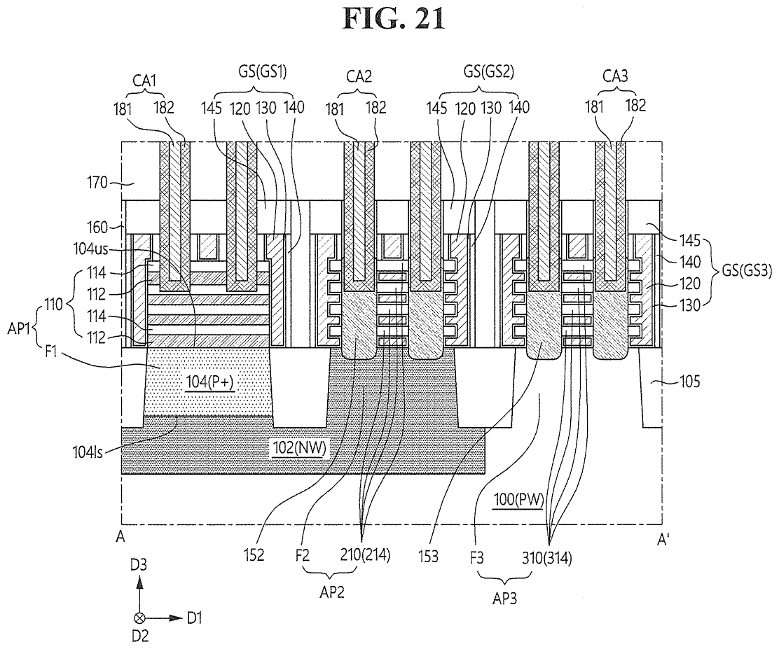

FIG. 20 is an exemplary plan view for describing a semiconductor device according to some exemplary embodiments. FIG. 21 is a cross-sectional view taken along line A-A′ of FIG. 20. In FIG. 21, other components except for an element separation pattern 105 are briefly illustrated. For convenience of explanation, points different from those described with reference to FIGS. 1 to 7 will be mainly described.

Referring to FIGS. 20 and 21, in some exemplary embodiments, the gate structure GS may include first to third gate structures GS1, GS2, and GS3.

The first gate structure GS1 may be disposed on the impurity implantation region 104. The first gate structure GS1 may be disposed on the first active pattern AP1. The first gate structure GS1 may intersect the first active pattern AP1. The first gate structure GS1 may intersect the first fin pattern F1. The first gate structure GS1 may cover the first fin structure 110. The first gate structure GS1 may cover an end or respective ends of the first fin structure 110.

The first contact CA1 may be disposed between adjacent first gate structures GS1.

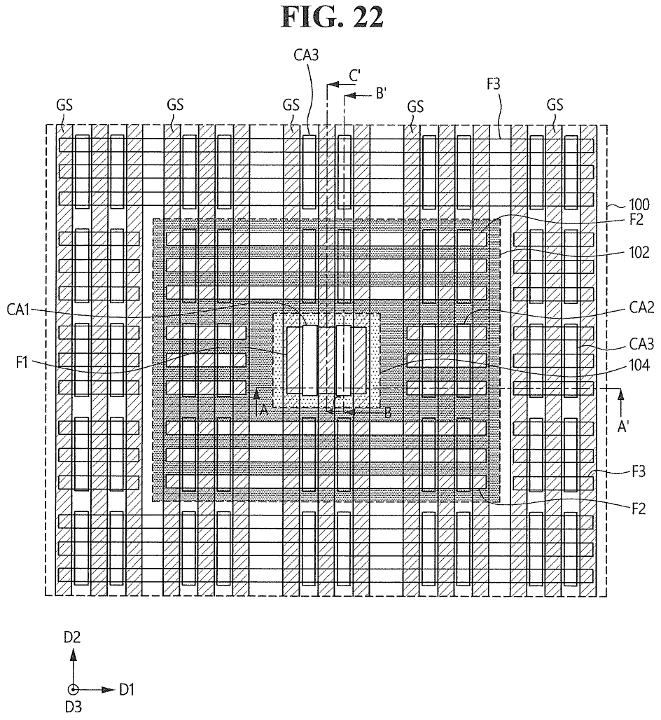

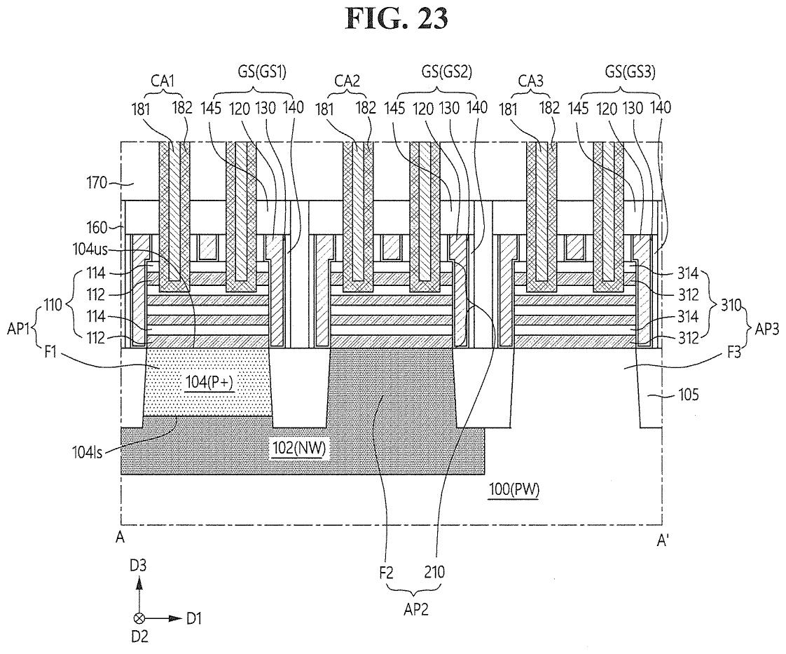

FIG. 22 is an exemplary plan view for describing a semiconductor device according to some exemplary embodiments. FIG. 23 is a cross-sectional view taken along line A-A′ of FIG. 22. In FIG. 22, other components except for an element separation pattern 105 are briefly illustrated. For convenience of explanation, points different from those described with reference to FIGS. 12 to 14 will be mainly described.

Referring to FIGS. 22 and 23, in some exemplary embodiments, the gate structure GS may include the first to third gate structures GS1, GS2, and GS3.

The first gate structure GS1 may be the first gate structure GS1 described with reference to FIGS. 20 and 21.

The second gate structure GS2 may cover the second fin structure 210. The second gate structure GS2 may cover an end or respective ends of the second fin structure 210. The second contact CA2 may be disposed between adjacent second gate structures GS2.

The third gate structure GS3 may cover the third fin structure 310. The third gate structure GS3 may cover an end or respective ends of the third fin structure 310. The third contact CA3 may be disposed between adjacent third gate structures GS3.

As used herein, when components or layers are referred to as “directly on” or “directly connected”, no intervening components or layers are present. Likewise, when components are “immediately” adjacent to one another, no intervening components may be present. The terms “comprises,” “comprising,” “includes” and/or “including,” when used herein, specify the presence of stated elements, but do not preclude the presence of additional elements. The term “and/or” includes any and all combinations of one or more of the associated listed items. Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. The device may be otherwise oriented (rotated 90 degrees or at other orientations), and the spatially relative descriptors used herein may be interpreted accordingly.

The exemplary embodiments of the present disclosure have been described above with reference to the accompanying drawings, but the present disclosure may be implemented in various different forms, and those skilled in the art to which the present disclosure pertains may understand that the present disclosure may be implemented in other specific forms without changing the inventive concepts of the present disclosure. Therefore, it should be understood that the exemplary embodiments described above are illustrative in all aspects and not restrictive.

What is claimed is:

1. A semiconductor device comprising:
a substrate having a first conductivity type;
a well region having a second conductivity type in the substrate;
an impurity implantation region having the first conductivity type in the well region;
an element separation pattern in the substrate;
a first fin pattern defined by the element separation pattern in the impurity implantation region;
a second fin pattern defined by the element separation pattern in the well region; and
a third fin pattern defined by the element separation pattern in the substrate,
wherein the first fin pattern is a single fin pattern, and
an entirety of a lower boundary of the impurity implantation region is in contact with the well region.

2. The semiconductor device of claim 1, further comprising:
a fin structure including sacrificial patterns and semiconductor patterns alternately stacked on the first fin pattern; and
a contact connected to one or more of the semiconductor patterns.

3. The semiconductor device of claim 2, wherein an entirety of an upper boundary of the impurity implantation region is in contact with the fin structure.

4. The semiconductor device of claim 2, further comprising a gate structure on the fin structure,
wherein the contact is on a side surface of the gate structure.

5. The semiconductor device of claim 1, further comprising:
first semiconductor patterns stacked on the second fin pattern;
a first gate structure on the first semiconductor patterns on the second fin pattern;
a first source/drain pattern connected to the first semiconductor patterns and having the second conductivity type, on a side surface of the first gate structure;
second semiconductor patterns stacked on the third fin pattern;
a second gate structure on the second semiconductor patterns on the third fin pattern; and
a second source/drain pattern connected to the second semiconductor patterns and having the first conductivity type, on a side surface of the second gate structure.

6. The semiconductor device of claim 5, wherein each of the first gate structure and the second gate structure includes a gate electrode, a gate insulating film, and a gate spacer.

7. The semiconductor device of claim 6, wherein the first gate structure further includes internal spacers on a side surface of the gate electrode between the first semiconductor patterns and on a side surface of the gate electrode between the second fin pattern and the first semiconductor patterns adjacent to each other.

8. The semiconductor device of claim 6, wherein the second gate structure further includes internal spacers on a side surface of the gate electrode between the second semiconductor patterns and on a side surface of the gate electrode between the third fin pattern and the second semiconductor patterns adjacent to each other.

9. The semiconductor device of claim 1, further comprising:
first sacrificial patterns and first semiconductor patterns alternately stacked on the second fin pattern; and
a first contact connected to one or more of the first semiconductor patterns.

10. The semiconductor device of claim 9, further comprising:
second sacrificial patterns and second semiconductor patterns alternately stacked on the third fin pattern; and
a second contact connected to one or more of the second semiconductor patterns.

11. The semiconductor device of claim 9, further comprising:
second semiconductor patterns stacked on the third fin pattern;
a gate structure on the second semiconductor patterns on the third fin pattern;
a source/drain pattern connected to the second semiconductor patterns and having the first conductivity type, on a side surface of the gate structure; and
a second contact connected to the source/drain pattern.

12. The semiconductor device of claim 1, further comprising:
first semiconductor patterns stacked on the second fin pattern;
a gate structure on the first semiconductor patterns on the second fin pattern;
a source/drain pattern connected to the first semiconductor patterns and having the second conductivity type, on a side surface of the gate structure;
a first contact connected to the source/drain pattern;
first sacrificial patterns and second semiconductor patterns alternately stacked on the third fin pattern; and
a second contact connected to one or more of the second semiconductor patterns.

13. A semiconductor device comprising:
a substrate having a first conductivity type;
a well region having a second conductivity type in the substrate;
an impurity implantation region having the first conductivity type in the well region; and
a first fin structure including first sacrificial patterns and first semiconductor patterns alternately stacked on the impurity implantation region,
wherein an entirety of an upper boundary of the impurity implantation region is in contact with the first fin structure.

14. The semiconductor device of claim 13, further comprising:
a plurality of second fin structures including second semiconductor patterns stacked on the well region and arranged in a first direction; and
a gate structure extending in the first direction on the plurality of second fin structures,
wherein in the first direction, a width of the first fin structure is greater than a width of the second fin structure.

15. The semiconductor device of claim 13, further comprising:
a plurality of second fin structures including second semiconductor patterns stacked on the substrate and arranged in a first direction; and
a gate structure extending in the first direction on the plurality of second fin structures,
wherein in the first direction, a width of the first fin structure is greater than a width of the second fin structure.

16. The semiconductor device of claim 13, wherein an entirety of a lower boundary of the impurity implantation region is in contact with the well region.

17. The semiconductor device of claim 13, further comprising:
second fin structures in the well region adjacent to the impurity implantation region and arranged in a first direction, wherein the well region is adjacent to the impurity implantation region in a second direction intersecting the first direction; and
third fin structures in the substrate adjacent to the impurity implantation region and arranged in the first direction, wherein the substrate is adjacent to the impurity implantation region in the second direction.

18. The semiconductor device of claim 17, wherein the second fin structures include second sacrificial patterns and second semiconductor patterns alternately stacked on the well region, and
the third fin structures include third sacrificial patterns and third semiconductor patterns alternately stacked on the substrate.

19. A semiconductor device comprising:
a substrate having a first conductivity type;
a well region having a second conductivity type in the substrate;
an impurity implantation region having the first conductivity type in the well region;
an element separation pattern in the substrate;
a first fin pattern defined by the element separation pattern in the impurity implantation region;
a second fin pattern defined by the element separation pattern in the well region;
a third fin pattern defined by the element separation pattern in the substrate;
a first fin structure including first sacrificial patterns and first semiconductor patterns alternately stacked on the first fin pattern in a first direction perpendicular to an upper surface of the substrate;
a second fin structure including second semiconductor patterns spaced apart from each other in the first direction on the second fin pattern; and
a third fin structure including third semiconductor patterns spaced apart from each other in the first direction on the third fin pattern,
wherein the first fin pattern is a single fin pattern and the first fin structure is a single fin structure, and in a second direction parallel to the upper surface of the substrate, a width of the first fin structure is the same as a width of the impurity implantation region.

20. The semiconductor device of claim 19, wherein, in a third direction parallel to the upper surface of the substrate and intersecting the second direction, a length of the first fin structure is the same as a length of the impurity implantation region.
